(19) United States
(12) Patent Application Publication
(10) Pub. No.: US 2013/0193448 A1
(43) Pub. Date: Aug. 1, 2013

(54) PATTERNED SUBSTRATE AND STACKED LIGHT EMITTING DIODE

(71) Applicant: Lextar Electronics Corporation, Hsinchu (TW)

(72) Inventors: Hsiu-Mei CHOU, Hsinchu City (TW); Jun-Rong CHEN, Taichung City (TW); Jhao-Cheng YE, Yunlin County (TW)

(73) Assignee: LEXTAR ELECTRONICS CORPORATION, Hsinchu (TW)

(21) Appl. No.: 13/752,370

(22) Filed: Jan. 28, 2013

(30) Foreign Application Priority Data
Jan. 30, 2012 (TW) 101102782

(51) Int. Cl. H01L 29/04; H01L 29/12; H01L 33/02; H01L 29/16

(52) U.S. Cl. CPC H01L 29/04; H01L 29/1608; H01L 29/12; H01L 33/02
USPC 257/77; 257/613; 257/627; 257/94

(57) ABSTRACT

A patterned substrate is provided, including: a substrate having a (0001) crystal plane and a plurality of alternatively arranged recess structures therein, thereby forming a plurality of alternatively arranged top surfaces; and a dielectric barrier layer covering the bottom surface and/or the sidewalls of the recess structures. Each of the alternatively arranged recess structures includes a bottom surface and a plurality of sidewalls surrounding the bottom surface.

### RELATED APPLICATIONS

This application claims priority of Taiwan Patent Application No. 101102782, filed on Jan. 30, 2012, the entirety of which is incorporated by reference herein.

### BACKGROUND

1. Technical Field

The present invention relates to a semiconductor structure and a method for fabricating the same, and in particularly to a method for fabricating a patterned substrate with epitaxial layers having improved crystal quality and stacked semiconductor structures with epitaxial layers having improved crystal quality.

2. Description of the Related Art

Light emitting diode (LED) is one of the most applied semiconductor devices in recent years, for having characteristics such as low power consumption, low pollution, and long lifetime. As such, the LED can be used in such as traffic lights, outdoor displays, and back light modules for displays.

Most of the modern advanced semiconductor electronic devices and electric optical device are fabricated by growth and stacking of epitaxy as a crystal, and a substrate is a key issue for the epitaxial growth of semiconductor structure in the devices. When the respective crystal constants of the substrate and the formed epitaxial layers are lattice mismatched with each other, the defect density in the epitaxial layer will be affected by the stress difference between the substrate and the subsequently formed epitaxial layers. The greater the defect density is, the more likely the excited electrons and holes recombine in traps of the crystal and release energy in non-radiation way. In this regard, the defect density is reduced by the improved crystal quality, and the internal quantum efficiency of LED can be increased as well.

To improve the crystal quality of the epitaxial layers, U.S. Pat. No. 7,445,673 discloses a method for laterally growing a semiconductor device, comprising a semiconductor layer and a partially mask layer disposed over the semiconductor substrate, wherein a plurality of growth openings are formed over the surface of the semiconductor layer using the mask layer, and the semiconductor layer exposed from the growth openings can adjust its epitaxial parameters through lateral homo-epitaxial growth method, to speed up a lateral growth thereof faster than its vertical growth, so as to bend the epitaxial defects and reduce penetrations of the defects from extending through the active lighting layer to its surface. However, the masks are all formed in the semiconductor layer and a current transmitting path will be thus affected.

To improve a patterned substrate, attempts also be tried by providing partial mask layer material, so as to improve the quality of the subsequent epitaxial layers. For instance, in Taiwan Patent No. M361771, a sapphire substrate and an epitaxial layer formed over the sapphire substrate are provided. A plurality of protrusions are disposed over the surface of the sapphire substrate, and each of the protrusions has a flat top surface and a mask layer is formed over the top surface. In the epitaxial growth, the epitaxial layer can be formed with an arrangement of low defect density using the sapphire substrate to perform epitaxial growth, and to improve the yield of subsequently formed elements.

Therefore, an improved method is needed to reduce above defects due to lattice mismatch between the substrate and the epitaxial layer, thereby forming improved epitaxial layers with better crystal quality and an optical electric device using the epitaxial layers with improved crystal quality.

### SUMMARY

In view of this, the invention provides a patterned substrate for forming an epitaxial layer with a better crystal quality and a stacked light emitting diode (LED) structure having the epitaxial layer with the better crystal quality to solve the above problems of undesired defect.

According an embodiment, the invention provides a patterned substrate, including: a substrate having a (0001) crystal plane and a plurality of alternatively arranged recess structures therein, such that a plurality of alternatively arranged top surfaces are formed, wherein each of the recess structures includes a bottom surface and a plurality of sidewalls surrounding the bottom surface; and a dielectric barrier layer covering the bottom surface and/or the sidewalls of the recess structures.

In other embodiments, the dielectric barrier layer further covers all or a part of each of the top surfaces of the substrate. The bottom surface is the (0001) crystal plane. The aforementioned material of the barrier layer is made of a low-conductive material such as silicon dioxide, silicon nitride or titanium dioxide. The substrate material may be one of sapphire, silicon, silicon carbide and the like. A yellow light lithographic process can be used for manufacturing the patterned substrate.

According to another embodiment, the invention provides a stacked LED structure, including: the patterned substrate, and an un-doped semiconductor epitaxial layer disposed on the dielectric barrier layer and the substrate.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIGS. 1-5 show fabrications of a stacked light emitting diode structure according to an embodiment of the invention;

FIGS. 6-10 show fabrications of a stacked light emitting diode structure according to another embodiment of the invention;

FIGS. 11-15 show fabrications of a stacked light emitting diode structure according to yet another embodiment of the invention;

FIG. 16 shows a stacked light emitting diode structure according to an embodiment of the invention;

FIGS. 17-21 show fabrications of a stacked light emitting diode structure according to an embodiment of the invention;

FIG. 22 shows a stacked light emitting diode structure according to an embodiment of the invention; and

FIGS. 23-27 show fabrications of a stacked light emitting diode structure according to an embodiment of the invention.

### DETAILED DESCRIPTION

The following description is of the best-contemplated mode of carrying out the invention. This description is made for the purpose of illustrating the general principles of the invention and should not be taken in a limiting sense. The scope of the invention is best determined by reference to the appended claims.

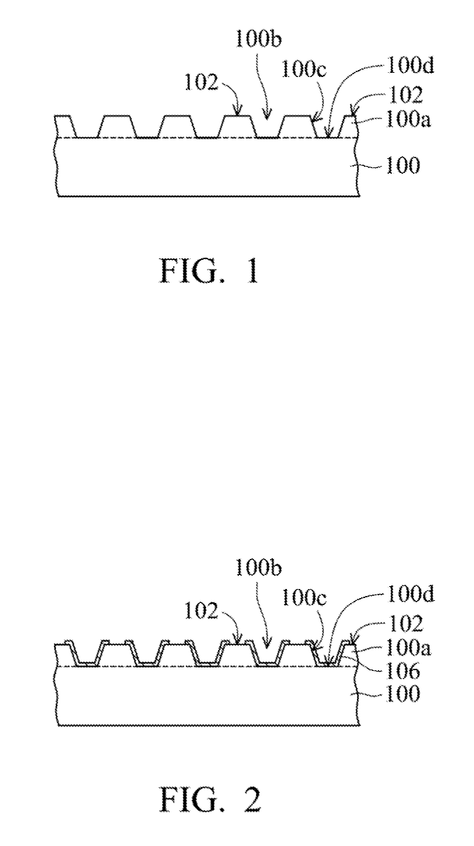

FIGS. 1-27 illustrate fabrications of a stacked light emitting device structure according to various embodiments of the invention.

Referring to FIGS. 1-5, a manufacturing process of a stacked LED structure is shown according to an embodiment of the invention. Referring to FIG. 1, a substrate 100 with a flat surface is provided first, such as the sapphire substrate, having a top surface 102 which is substantially a flat surface. The material of the substrate 100 may include sapphire, silicon, silicon carbide and so on. Then, by applying a suitable patterned mask (not shown), the photolithography is used to define an etching area, and then by implementing an etching process (not shown), several portions of the substrate 100 are partially removed from the top surface 102, so as to form several separated islands 100a on the substrate 100. These separated islands 100a define several alternatively arranged recess structures 100b therebetween. These recess structures 100b may be a trench or an opening, which is formed as defining by a sidewall 100c of the adjacent island 100a and a bottom surface 100d surrounded by several sidewalls 100c of the adjacent island 100a. Herein, crystalline planes of the top surface 102 of each island 100a and the bottom surface 100d of each recess structure 100b are (0001) crystal planes.

Referring to FIG. 2, a layer of low-conducive dielectric material is deposited on the substrate 100, such as silicon dioxide. The top surface 102 and the sidewall 100c of each island 100a and the bottom surface 100d of each recess structure are covered accordingly by this layer of dielectric material. Then by applying the suitable patterned mask (not shown) and implementing the etching process (not shown), the dielectric material located on the top surface 102 of each island 100a is partially removed, so as to partially expose the top surface 102 of each island 100a and form a dielectric barrier layer 106 in each recess structure 100b. Herein, the top surface 102 of each island 100a is partially covered by the dielectric barrier layer 106, and the sidewall 100c of each island 100a and the bottom surface 100d in each recess structure 100b are completely covered by the dielectric barrier layer 106. The material of the dielectric barrier layer 106 may include silicon dioxide, silicon nitride or titanium dioxide and other dielectric materials, which may be formed through a metal organic chemical vapor deposition (MOCVD), a hydride vapor phase epitaxy (HVPE) and other deposition processes.

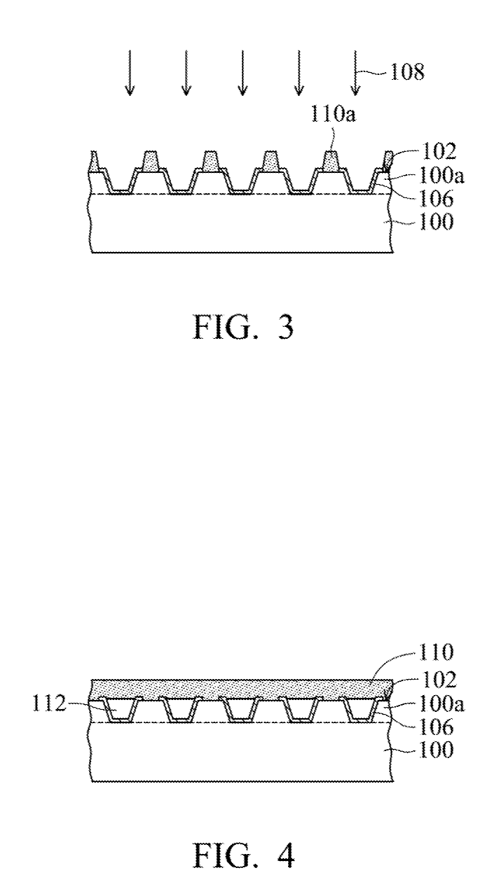

Referring to FIG. 3, an epitaxial growth process 108 is implemented, such as an epitaxial growth process of the MOCVD, HVPE, so as to grow up an un-doped semiconductor epitaxial layer 110a on the substrate 100. The material is for example aluminum indium gallium nitride, and the indium content and aluminum content in this un-doped semiconductor epitaxial layer 110a can be adjusted through the epitaxial parameter. Herein, since the top surface 102 of each island 100a is partially exposed, the un-doped semiconductor epitaxial layer 110a performs the epitaxial growth at the (0001) crystal plane of the partially-exposed top surface 102 of the islands 100a, thereby growing up to form an un-doped semiconductor epitaxial layer 110a. Herein, a main growth direction of the un-doped semiconductor epitaxial layer 110a is a direction perpendicular to the top surface 102 of each island 110a.

Referring to FIG. 4, the epitaxial growth process 108 continues to be implemented, and with the extension of the time of the epitaxial growth process 108 and the adjustment of the epitaxial parameters (such as temperature and pressure), in addition to continuing to grow up towards the direction perpendicular to the top surface 102 of each island 110a, the un-doped semiconductor epitaxial layer 110a (referring to FIG. 3) higher than the dielectric barrier layer 106 also grows up towards the direction horizontal to the top surface 102 of each island 110a, thereby causing a side merging with the un-doped semiconductor epitaxial layer 110a formed on the top surface 102 of the adjacent island 110a and finally forming an un-doped semiconductor epitaxial layer 110 having a flat surface as shown in FIG. 4.

As shown in FIG. 4, the recess structure 100b located between adjacent islands 1000a is not filled up of this un-doped semiconductor epitaxial layer 110 at this time, and a gap 112 exists among each recess structure 100b, which locates between the un-doped semiconductor epitaxial layer 110 and the adjacent island 100a, and the adjacent dielectric barrier layer 106 as well as the un-doped semiconductor epitaxial layer 110. As an embodiment, the gap 112 between the recess structure 100b and the un-doped semiconductor epitaxial layer 110 has a height ranging from 0.1-2 μm.

As shown in FIG. 4, since the formed un-doped semiconductor epitaxial layer 110 performs the epitaxial growth at the (0001) crystal plane of the partially-exposed top surface 102 of each island 100a in a patterned substrate as shown in FIG. 2, the epitaxial direction in the formed un-doped semiconductor epitaxial layer 110 can be controlled, thereby reducing the problem of threading dislocations caused by mismatch of the lattice between the material of the un-doped semiconductor epitaxial layer 110 and the material of the substrate 100. In addition, since the material of the un-doped semiconductor epitaxial layer 110 performs the epitaxial growth only at part of the (0001) crystal plane, generation of the defect density in the un-doped semiconductor epitaxial layer 110 can be reduced. Therefore, the un-doped semiconductor epitaxial layer 110 formed on a patterned substrate shown in FIG. 4 has a better epitaxial quality, so it is beneficial for improving light emitting efficiency and reliability of the electronic element and the photoelectric element such as the LED formed thereon.

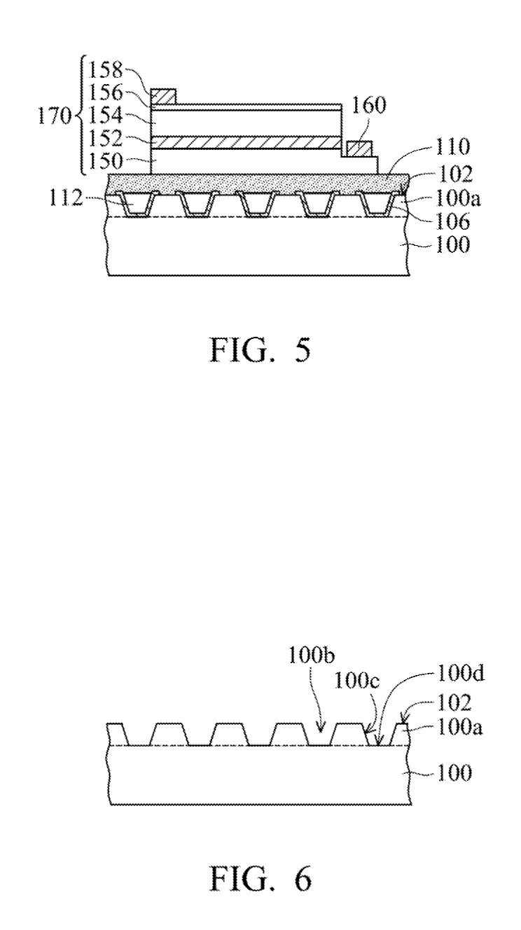

Referring to FIG. 5, then a conventional process (not shown) may be employed to form a light emitting element structure 170 on the un-doped semiconductor epitaxial layer 110. Herein, the light emitting element structure 170 mainly includes a n-type semiconductor epitaxial layer 150, an active layer 152, a p-type semiconductor epitaxial layer 154, a transparent conductive layer 156, electrodes 158 and 160 that are used for forming the epitaxial layer sequentially. As shown in FIG. 5, the active layer 152 is located on a part of areas of the n-type semiconductor epitaxial layer 150, while a part of areas of the n-type semiconductor epitaxial layer 150 are exposed. The p-type semiconductor epitaxial layer 154 is located on the active layer 152, while the transparent conductive layer 156 is formed on the p-type semiconductor epitaxial layer 154, and the electrode 158 may be formed on the transparent conductive layer 156. Another electrode 160 may be formed on a part of areas of the n-type semiconductor epitaxial layer 150 that are exposed. In another embodiment, the transparent conductive layer 156 is a selective film layer, and so it may be omitted, such that the electrode 158 may be directly formed on the p-type semiconductor epitaxial layer 154. The above n-type semiconductor epitaxial layer 150 is, for example, a Si-doped n-type semiconductor epitaxial layer, while the above p-type semiconductor epitaxial layer 154 is, for example, an Mg-doped p-type semiconductor epitaxial layer. The n-type semiconductor epitaxial layer 150 and the p-type semiconductor epitaxial layer 154 may include aluminum indium gallium nitride (AlₓIn_{y}Ga_{1-x-y}N, 0≦x≦1, 0≦y≦1) and other epitaxial materials, and the indium content and the aluminum content may be adjusted by the epitaxial parameter. The active layer 152 may be, for example, indium gallium nitride/gallium nitride multiple quantum wells of indium gallium nitride and gallium nitride, and the transparent conductive layer 156 may include indium tin oxide (ITO), nickel (Ni)/gold (Au) structure and other materials.

Since the un-doped semiconductor epitaxial layer 110 exists below the light emitting element 170, the dielectric barrier layer 106 is used and the epitaxial parameter is adjusted to make the un-doped semiconductor epitaxial layer 110 perform lateral epitaxial growth, such that the epitaxial layer has less defect problems, and the efficiency and reliability of the light emitting element 170 formed on the epitaxial layer 110 may be improved. Additionally, since several gaps 112 and the dielectric barrier layer 106 are formed below the un-doped semiconductor epitaxial layer 110, and since different refraction coefficients exist among the dielectric barrier layer 106 and the substrate 100 and the un-doped semiconductor epitaxial layer 110 and the gaps 112 may act as a scattering center of photons, the light emitted from the active layer 152 may pass through these gaps 112 and the dielectric barrier layer 106 and then a refraction angle and a reflection angle of the light are changed, so as to enhance a light extraction efficiency of the light emitting element 170.

Referring to FIGS. 6-10, they show the manufacturing of a stacked LED structure according to another embodiment of the invention. Herein, the embodiment as shown in FIGS. 6-10 is a variation of the embodiment shown in FIGS. 1-4, and so a same reference number refers to a same element herein.

Referring to FIG. 6, the substrate 100 with the flat surface is firstly provided, which has the top surface 102. The substrate 100 may include sapphire, silicon, silicon carbide and other materials. Then, by applying the suitable patterned mask (not shown), the photolithography is used to define the etching area, and then by implementing the etching process (not shown), several portions of the substrate 100 are partially removed from the top surface 102, so as to form several separated islands 100a on the substrate 100. These separated islands 100a define several alternatively arranged recess structures 100b therein. These recess structures 100b may be the trench or the opening, which is defined and formed by the sidewall 100c of the adjacent island 100a and the bottom surface 1000d surrounded by several sidewalls 100c of the adjacent island 100a. Herein, the crystalline planes of the top surface 102 of each island 100a and the bottom surface 100d of each recess structure 100b are the kind of (0001) crystal plane.

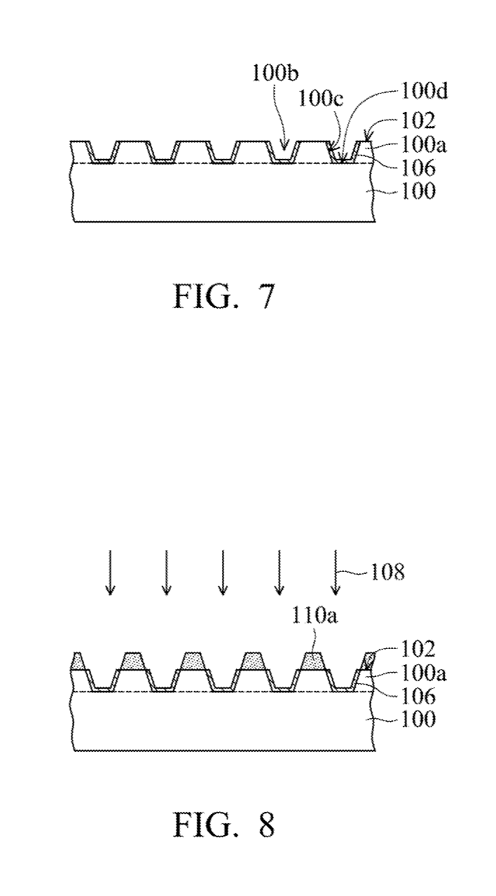

Referring to FIG. 7, then, a layer of dielectric material is deposited on the substrate 100, for example: silicon dioxide. The top surface 102 and the sidewall 100c of each island 100a and the bottom surface 100d of each recess structure are covered correspondingly by this layer of dielectric material. Then, by applying the suitable patterned mask (not shown) and implementing the etching process (not shown), the dielectric material located on the top surface 102 of each island 100a is completely removed, so as to completely expose the top surface 102 of each of the semiconductor islands 100a and form the dielectric barrier layer 106 in each recess structure 100b. Herein, the dielectric barrier layer 106 completely covers the sidewall 100c of each island 100a and the bottom surface 100d in each recess structure 100b, but not covers all the top surface 102 of each island 100a. The dielectric barrier layer 106 may include silicon dioxide, silicon nitride or titanium dioxide and other dielectric materials, and may be formed by the MOCVD, the HVPE and other deposition processes.

Referring to FIG. 8, the epitaxial growth process 108 is implemented, for example, the epitaxial growth process of the MOCVD, so as to grow up the un-doped semiconductor epitaxial layer 110a such as the gallium nitride material on the substrate 100. Herein, since the top surface 102 of each island 100a is completely exposed, the un-doped semiconductor epitaxial layer 110a performs the epitaxial growth from the (0001) crystal plane of the top surface 102 of each island 100a, thereby growing up to form the un-doped semiconductor epitaxial layer 110a. Herein, the main growth direction of the un-doped semiconductor epitaxial layer 110a is the direction perpendicular to the top surface 102 of each island 110a.

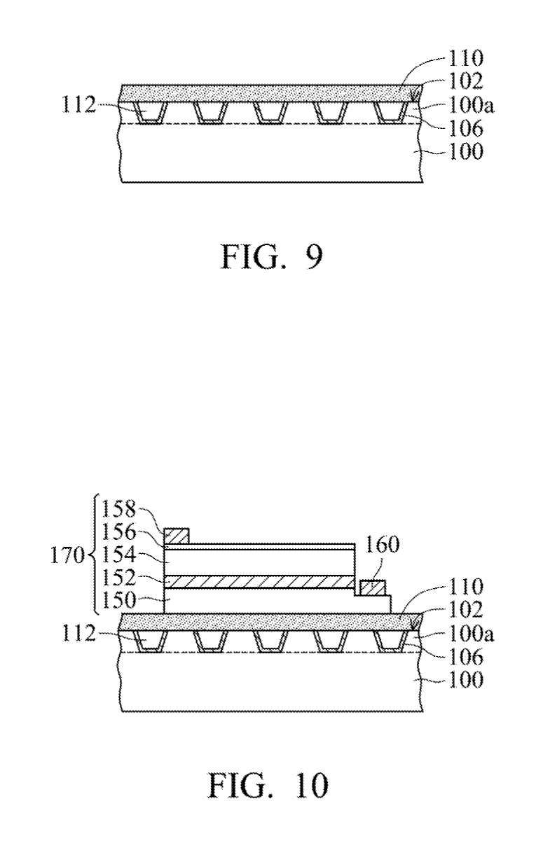

Referring to FIG. 9, then, the epitaxial growth process 108 continues to be implemented, and with the extension of the time of the epitaxial growth process 108, in addition to continue to grow up towards the direction perpendicular to the top surface 102 of each island 110a, the un-doped semiconductor epitaxial layer 110a (see FIG. 8) higher than the dielectric barrier layer 106 also grows up towards the direction horizontal to the top surface 102 of each island 110a, thereby generating a side merging with the un-doped semiconductor epitaxial layer 110a located on the top surface 102 of the adjacent island 110a and finally forming the un-doped semiconductor epitaxial layer 110 having the flat surface as shown in FIG. 9.

As shown in FIG. 9, the recess structure 100b between adjacent islands 100a is not filled with this un-doped semiconductor epitaxial layer 110 at this time, while the gap 112 may exist among each recess structure 100b between the un-doped semiconductor epitaxial layer 110 and the adjacent island 100a and the adjacent dielectric barrier layer 106 as well as the un-doped semiconductor epitaxial layer 110. As an embodiment, the gap 112 between the recess structure 100b and the un-doped semiconductor epitaxial layer 110 has a height ranging from 0.1-2 μm. The formed un-doped semiconductor epitaxial layer 110 performs the epitaxial growth from the (0001) crystal plane of the completely-exposed top surface 102 of each island 100a in the patterned substrate as shown in FIG. 7, therefore, the epitaxial direction in the formed un-doped semiconductor epitaxial layer 110 may be controlled, thereby reducing the threading dislocations due to the mismatch of the lattice between the material of the un-doped semiconductor epitaxial layer 110 and the material of the substrate 100. In addition, since the material of the un-doped semiconductor epitaxial layer 110 performs the epitaxial growth only from the (0001) crystal plane, generation of the defect density in the un-doped semiconductor epitaxial layer 110 may be reduced. Therefore, since the un-doped semiconductor epitaxial layer 110 formed on the patterned substrate shown in FIG. 9 has the better epitaxial quality, it is beneficial to improve the light emitting efficiency and reliability of the electronic element and the photoelectric element such as the LED formed thereon.

Referring to FIG. 10, then, the conventional process (not shown) may be employed to form the light emitting element 170 in the above embodiment on the un-doped semiconductor epitaxial layer 110. Since the un-doped semiconductor epitaxial layer 110 exists below the light emitting element 170, the defect problems are less and the epitaxial quality is better, such that the light emitting efficiency and reliability of the light emitting element 170 formed on the un-doped semiconductor epitaxial layer 110 may be improved. Additionally, since several gaps 112 and the dielectric barrier layer 106 are formed below the un-doped semiconductor epitaxial layer 110, and since different refraction coefficients exist among the dielectric barrier layer 106 and the substrate 100 and the un-doped semiconductor epitaxial layer 110 and the gaps 112 may act as the scattering center of the photons, the light emitted from the active layer 152 may pass through these gaps 112 and the dielectric barrier layer 106 and then the refraction coefficient of the light is different, so as to enhance the light extraction efficiency of the light emitting element 170. As an embodiment, the gap 112 between the recess structure 100b and the un-doped semiconductor epitaxial layer 110 has a height ranging from 0.1-2 μm.

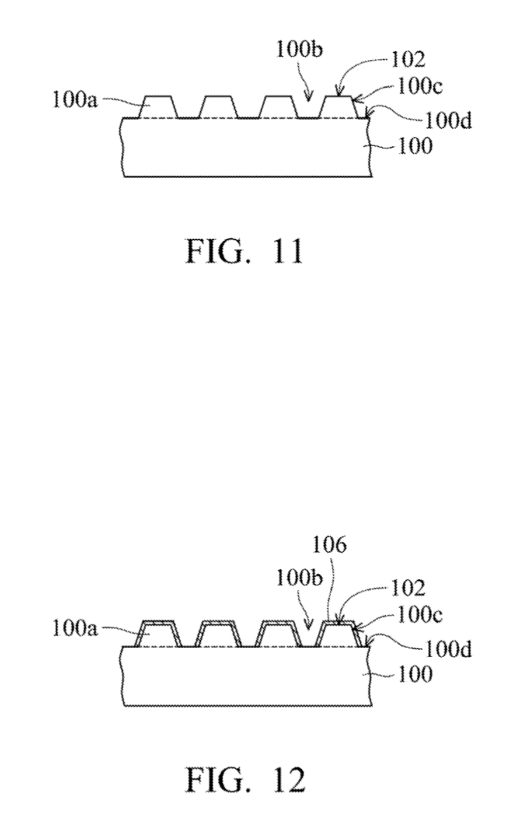

Referring to FIGS. 11-15, they show the manufacturing of a stacked LED structure according to yet another embodiment of the invention. Herein, the embodiment as shown in FIGS. 11-15 is the variation of the embodiment shown in FIGS. 1-4, and so the same reference number refers to the same element herein.

Referring to FIG. 11, the substrate 100 with the flat surface is firstly provided, which has the top surface 102. The substrate 100 may include sapphire, silicon, silicon carbide and other materials. Then, by applying the suitable patterned mask (not shown) and implementing the etching process (not shown), several portions of the substrate 100 are partially removed from the top surface 102, so as to form several separated islands 100a on the substrate 100. These separated islands 100a define several alternatively arranged recess structures 100b therein. These recess structures 100b may be the trench or the opening, which is defined and formed by the sidewall 100c of the adjacent island 100a and the bottom surface 100d surrounded by several sidewalls 100c of the adjacent island 100a. Herein, the crystalline planes of the top surface 102 of each island 100a and the bottom surface 100d of each recess structure 100b are the kind of (0001) crystal plane.

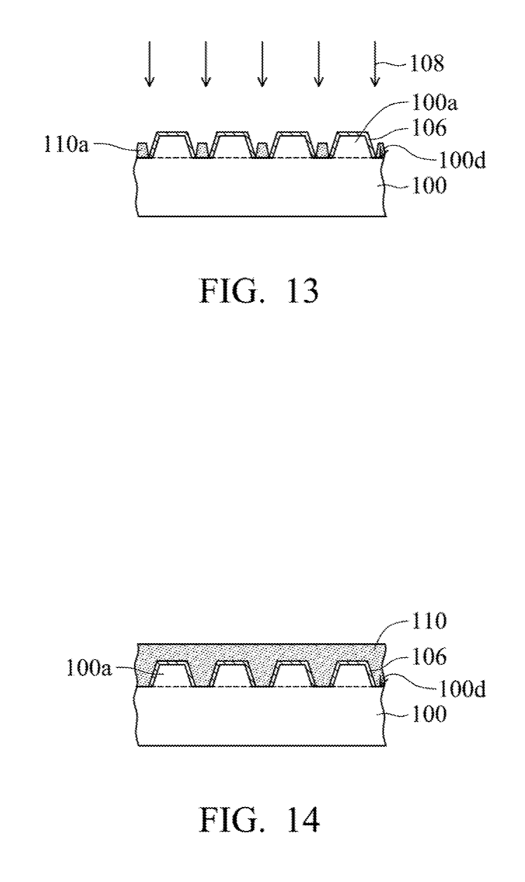

Referring to FIG. 12, then, a layer of dielectric material is deposited on the substrate 100, for example: silicon dioxide. The top surface 102 and the sidewall 100c of each island 100a and the bottom surface 100d of each recess structure are covered correspondingly by this layer of dielectric material. Then, by applying the suitable patterned mask (not shown) and implementing the etching process (not shown), the dielectric material located on the bottom surface 100d in each recess structure 100b is only partially removed, so as to partially expose the bottom surface 100d in each recess structure 100 and form the dielectric barrier layer 106 in each island 100a. Herein, the sidewall 100c and the top surface 102 of each island 100a are completely covered by the dielectric barrier layer 106, but by which the bottom surface 100d in each recess structure 100b is partially exposed. The dielectric barrier layer 106 may include silicon dioxide, silicon nitride or titanium dioxide and other dielectric materials, and which may be formed by the MOCVD, the HVPE and other deposition processes.

Referring to FIG. 13, then, the epitaxial growth process 108 is implemented, for example, the epitaxial growth process of the MOCVD and the HVPE, so as to grow up the un-doped semiconductor epitaxial layer 110a such as the gallium nitride material on the substrate 100. Herein, since the bottom surface 100d in each recess structure 100b is partially exposed, the un-doped semiconductor epitaxial layer 110a performs the epitaxial growth from the (0001) crystal plane of the bottom surface 100d in each recess structure 100b, thereby growing up to form the un-doped semiconductor epitaxial layer 110a. Herein, the main growth direction of the un-doped semiconductor epitaxial layer 110a is the direction perpendicular to the bottom surface 100d in each recess structure 1100b.

Referring to FIG. 14, then, the epitaxial growth process 108 continues to be implemented, and with the extension of the time of the epitaxial growth process 108, in addition to continue to grow up towards the direction perpendicular to the bottom surface 100d in each recess structure 100b, the un-doped semiconductor epitaxial layer 110a (see FIG. 13) higher than the dielectric barrier layer 106 and the islands 100a also grows up towards the direction horizontal to the bottom surface 100d in each recess structure 100b, thereby generating the side merging with the un-doped semiconductor epitaxial layer 110a higher than the top surface 102 of the adjacent island 110a and finally forming the un-doped semiconductor epitaxial layer 110 having the flat surface as shown in FIG. 14.

As shown in FIG. 14, the recess structure 100b between adjacent islands 100a is not filled with this un-doped semiconductor epitaxial layer 110 at this time, while no gap may exist among each recess structure 100b between the un-doped semiconductor epitaxial layer 110 and the adjacent island 100a and the adjacent dielectric barrier layer 106 as well as the un-doped semiconductor epitaxial layer 110.

As shown in FIG. 14, the formed un-doped semiconductor epitaxial layer 110 performs the epitaxial growth from the (0001) crystal plane of the bottom surface 100d of each recess structure 100b in the patterned substrate as shown in FIG. 12, therefore, the epitaxial direction in the formed un-doped semiconductor epitaxial layer 110 may be controlled, thereby reducing the threading dislocations due to the mismatch of the lattice between the material of the un-doped semiconductor epitaxial layer 110 and the material of the substrate 100. In addition, since the material of the un-doped semiconductor epitaxial layer 110 performs the epitaxial growth only from the (0001) crystal plane, generation of the defect density in the un-doped semiconductor epitaxial layer 110 may be reduced. Therefore, since the un-doped semiconductor epitaxial layer 110 formed on the patterned substrate shown in FIG. 12 has less defect problems, it may have the better epitaxial quality, and so it is beneficial to improve the efficiency and reliability of the electronic element and the photoelectric element such as the LED formed thereon.

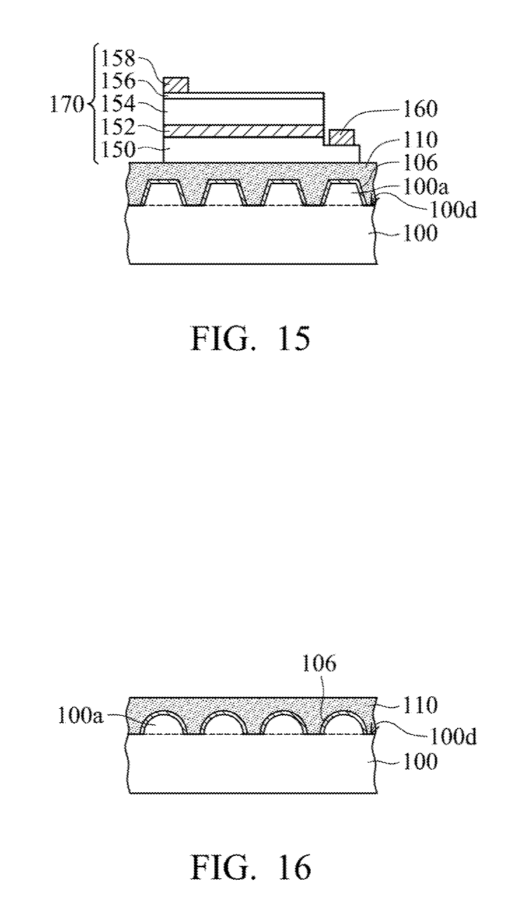

Referring to FIG. 15, then, the conventional process (not shown) may be employed to form the light emitting element 170 in the above embodiment on the un-doped semiconductor epitaxial layer 110. Since the un-doped semiconductor epitaxial layer 110 exists below the light emitting element 170, the defect problems are less and the epitaxial quality is better, such that the light emitting efficiency and reliability of the light emitting element 170 formed on the un-doped semiconductor epitaxial layer 110 may be improved. Additionally, since several dielectric barrier layers 106 are formed below the un-doped semiconductor epitaxial layer 110, and since different refraction coefficients exist among the dielectric barrier layer 106 and the substrate 100 and the un-doped semiconductor epitaxial layer 110, the light emitted from the active layer 152 may be scattered by these dielectric barrier layers 106, so as to enhance the light extraction efficiency of the light emitting element 170.

Referring to FIG. 16, it shows a stacked LED structure according to an embodiment of the invention, which is the variation of the embodiment shown in FIG. 14. In this embodiment, a profile of the island 110a in the stacked LED structure is not limited to a tapered profile shown in FIG. 14, for example, the top surface of the island 110a is an arc shape. As shown in FIG. 16, the island 110a has a approximate semicircle profile, while the dielectric barrier layer 106 may formed on the surface of this approximate semicircle island 100a, and the un-doped semiconductor epitaxial layer 110 grows up from the bottom surface 100d of the recess structure between adjacent semiconductor islands 100a and fills with the recess structure.

In the stacked LED structure as shown in FIG. 16, the above light emitting element 170 (not shown herein) may also be formed on the un-doped semiconductor epitaxial layer 110, while the light emitting element formed on the un-doped semiconductor epitaxial layer 110 may also have the same advantages as described in the above embodiments.

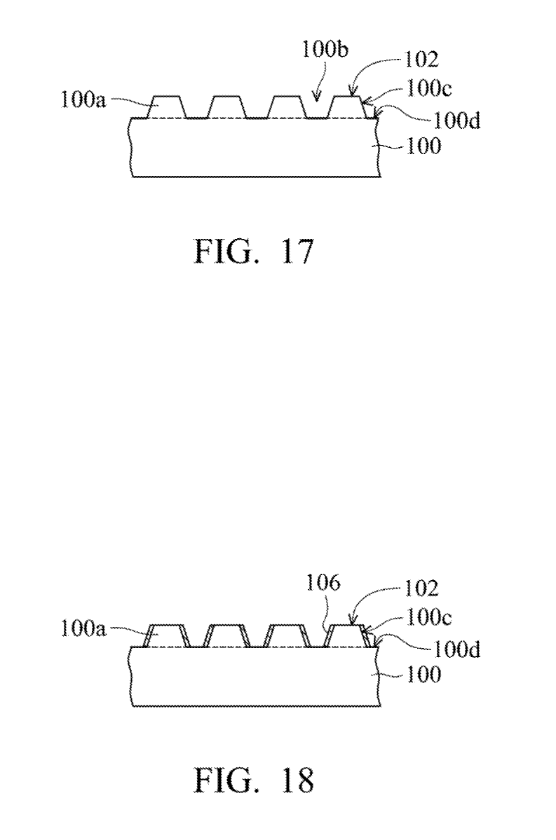

Referring to FIGS. 17-21, they show the manufacturing of a stacked LED structure according to yet another embodiment of the invention. Herein, the embodiment as shown in FIGS. 17-21 is the variation of the embodiment shown in FIGS. 1-4, and so the same reference number refers to the same element herein.

Referring to FIG. 17, the substrate 100 with the flat surface is firstly provided, which has the top surface 102. The substrate 100 may include sapphire, silicon, silicon carbide and other materials. Then, by applying the suitable patterned mask (not shown) and implementing the etching process (not shown), several portions of the substrate 100 are partially removed from the top surface 102, so as to form several separated islands 1000a on the substrate 100. These separated islands 1000a define several alternatively arranged recess structures 100b therein. These recess structures 100b may be the trench or the opening, which is defined and formed by the sidewalls 100c of adjacent several islands 100a and the bottom surface 100d surrounded by several sidewalls 100c of the adjacent island 100a. Herein, the crystalline planes of the top surface 102 of each island 100a and the bottom surface 1000d of each recess structure 100b are the kind of (0001) crystal plane.

Referring to FIG. 18, a layer of dielectric material is deposited on the substrate 100. The sidewall 100c of each island 100a and the bottom surface 100d of each recess structure are covered correspondingly by this layer of dielectric material. Then, the suitable patterned mask (not shown) is applied and the etching process (not shown) is implemented to completely remove the dielectric material located on the top surface 102 of each island 100a and remove the dielectric material located on the bottom surface 100d in each recess structure 100b, so as to completely expose the top surface of each island 100a and expose the bottom surface 100d in each recess structure 100b, and form the dielectric barrier layer 106 on the sidewall 100c of each island 100a. Herein, the dielectric barrier layer 106 covers only the sidewall 100c of each island 100a, but not all the top surface 102 of each island 100a and the bottom surface 100d. The dielectric barrier layer 106 includes silicon dioxide, silicon nitride or titanium dioxide and other dielectric materials, and may be formed by the MOCVD, the HVPE and other deposition processes.

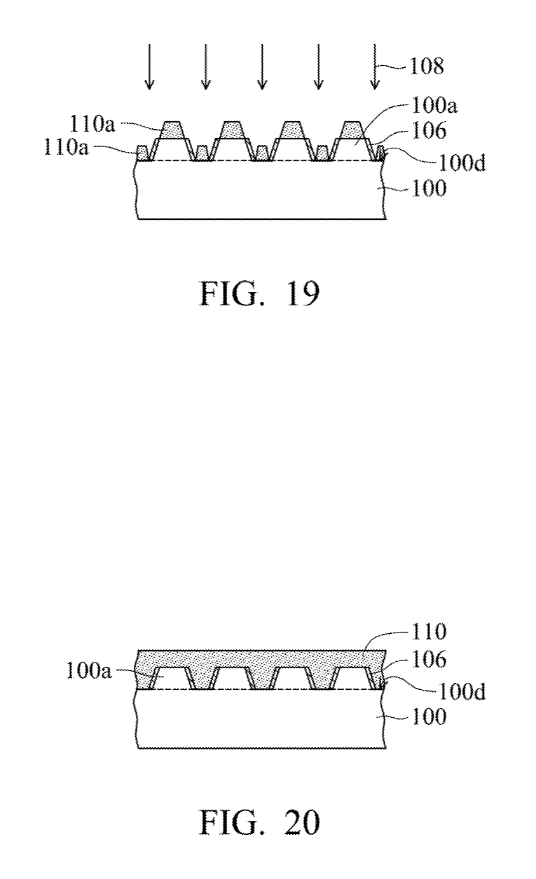

Referring to FIG. 19, the epitaxial growth process 108 is implemented, for example, the deposition process of the MOCVD, HVPE, so as to grow up the epitaxial layer 110a such as the gallium nitride material on the substrate 100. Herein, since the top surface 102 of each island 100a and the bottom surface 100d in each recess structure 100b are completely exposed, the epitaxial layer 110a performs the epitaxial growth from the (0001) crystal plane of the top surface 102 of each island 100a and the bottom surface 100d in each recess structure 100b, thereby growing up to form the un-doped semiconductor epitaxial layer 110a. Herein, the main growth direction of the un-doped semiconductor epitaxial layer 110a is the direction perpendicular to the top surface 102 of each island 100a and the bottom surface 100d in each recess structure 100b.

Referring to FIG. 20, the epitaxial growth process 108 continues to be implemented, and with the extension of the time of the epitaxial growth process 108, in addition to continue to face towards the direction perpendicular to the top surface 102 of each island 100a and the bottom surface 100d of each recess structure 100b, the un-doped semiconductor epitaxial layer 110a (see FIG. 19) higher than the dielectric barrier layer 106 and the islands 100a also faces towards the direction horizontal to the top surface 102 of each island 100a and the bottom surface 100d of each recess structure 100b, thereby generating the side merging with the un-doped semiconductor epitaxial layer 110a higher than the top surface 102 of the adjacent island 110a and finally forming the un-doped semiconductor epitaxial layer 110 having the flat surface as shown in FIG. 20.

As shown in FIG. 20, the recess structure 100b between adjacent islands 100a is not filled with this un-doped semiconductor epitaxial layer 110 at this time, while no gap may exist among each recess structure 100b between the un-doped semiconductor epitaxial layer 110 and the adjacent island 100a and the adjacent dielectric barrier layer 106 as well as the un-doped semiconductor epitaxial layer 110.

As shown in FIG. 20, the formed un-doped semiconductor epitaxial layer 110 performs the epitaxial growth from the (0001) crystal plane of the top surface 102 of each island 100a and the bottom surface 100d of each recess structure 100b in the patterned substrate as shown in FIG. 18, therefore, the epitaxial direction in the formed un-doped semiconductor epitaxial layer 110 may be controlled.

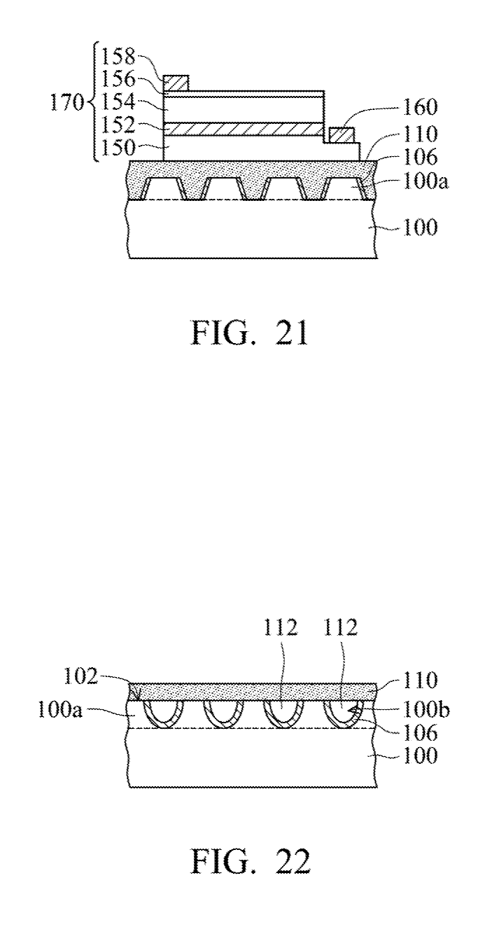

Referring to FIG. 21, then, the conventional process (not shown) may be employed to form the light emitting element 170 in the above embodiment on the un-doped semiconductor epitaxial layer 110. Since the un-doped semiconductor epitaxial layer 110 exists below the light emitting element 170, the defect problems are less and the epitaxial quality is better, such that the efficiency and reliability of the light emitting element 170 formed on the un-doped semiconductor epitaxial layer 110 may be improved. Additionally, since several dielectric barrier layers 106 are formed below the un-doped semiconductor epitaxial layer 110, and since different refraction coefficients exist among the dielectric barrier layer 106 and the substrate 100 and the un-doped semiconductor epitaxial layer 110, the light emitted from the active layer 152 may be scattered by these dielectric barrier layers 106 to enhance the light extraction efficiency of the light emitting element 170.

Referring to FIG. 22, it shows a stacked LED structure according to an embodiment of the invention, which is the variation of the embodiment shown in FIG. 16. In this embodiment, the profile of the recess structure 100b in the stacked LED structure is not limited to the tapered profile shown in FIG. 16, which may have the approximate semicircle profile, while the dielectric barrier layer 106 may formed on the sidewall surface of this approximate semicircle recess structure 100b, and the un-doped semiconductor epitaxial layer 110 grows up from the top surface 102 of the island 100a adjacent to each recess structure 100b and the gap 112 exists between the un-doped semiconductor epitaxial layer 110 and the recess structure 100b. As an embodiment, the gap 112 between the recess structure 100b and the un-doped semiconductor epitaxial layer 110 has a height ranging from 0.1-2 μm. In the stacked LED structure as shown in FIG. 22, the above light emitting element 170 (not shown herein) may also be formed on the un-doped semiconductor epitaxial layer 110, while the light emitting element formed on the un-doped semiconductor epitaxial layer 110 may also have the same advantages as described in the above embodiments.

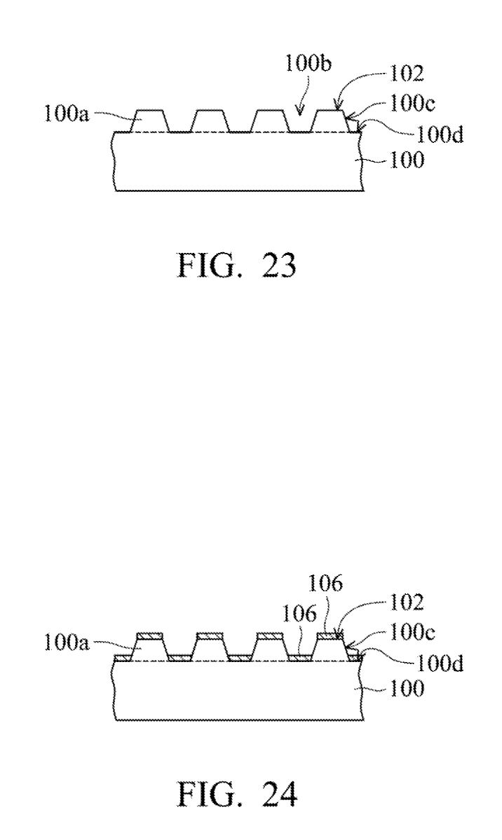

Referring to FIGS. 23-27, they show the manufacturing of a stacked LED structure according to yet another embodiment of the invention. Herein, the embodiment as shown in FIGS. 23-27 is the variation of the embodiment shown in FIGS. 1-4, and so the same reference number refers to the same element herein.

Referring to FIG. 23, the substrate 100 with the flat surface is firstly provided, which has the top surface 102. The substrate 100 may include sapphire, silicon, silicon carbide and other materials. Then, by applying the suitable patterned mask (not shown) and implementing the etching process (not shown), several portions of the substrate 100 are partially removed from the top surface 102, so as to form several separated islands 100a on the substrate 100. These separated islands 100a define several alternatively arranged recess structures 100b therein. These recess structures 100b may be the trench or the opening, which is defined and formed by the sidewalls 100c of the adjacent several islands 100a and the bottom surface 100d surrounded by several sidewalls 100c of the adjacent island 100a. Herein, the crystalline planes of the top surface 102 of each island 100a and the bottom surface 100d of each recess structure 100b is the kind of (0001) crystal plane.

Referring to FIG. 24, then, a layer of dielectric material is deposited on the substrate 100, for example: silicon dioxide. The top surface 102 of each island and the bottom surface 100d are covered correspondingly by this layer of dielectric material. Then, by applying the suitable patterned mask (not shown) and implementing the etching process (not shown), only the top surface 102 of each island and the bottom surface 100d are covered by the dielectric material layer, so as to only partially expose the sidewall 100c of each island 100a and respectively form the dielectric barrier layer 106 on the top surface 102 of each island 100a and the bottom surface 100d of each recess structure. Herein, only the top surface 102 of each island 100a and the bottom surface 100d of each recess structure are covered by the dielectric barrier layer 106, but by which the sidewall 100c of each island 100a is not completely covered. The dielectric barrier layer 106 may include silicon dioxide, silicon nitride or titanium dioxide and other dielectric materials, and which may be formed by the MOCVD, the HVPE and other deposition processes.

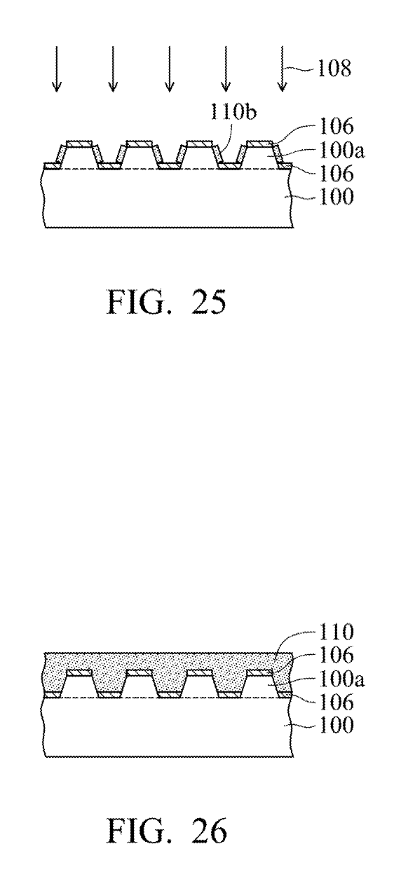

Referring to FIG. 25, then, the epitaxial growth process 108 is implemented, for example, formed by the deposition process of the MOCVD and the HVPE, so as to grow up an un-doped semiconductor epitaxial layer 110b such as the aluminum nitride material on the substrate 100. Herein, since only the sidewall 100c of each island 100a is partially exposed, the un-doped semiconductor epitaxial layer 110a performs the epitaxial growth from an inclined surface of the sidewall 100c of each island 100a, thereby growing up to form the un-doped semiconductor epitaxial layer 110b. Herein, the main growth direction of the un-doped semiconductor epitaxial layer 110b is the direction perpendicular to the inclined surface of each island 100a.

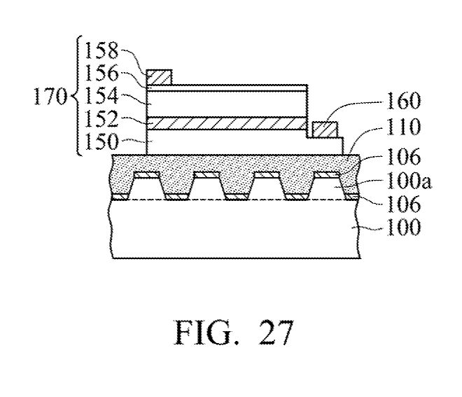

Referring to FIG. 26, then, the epitaxial growth process 108 continues to be implemented, and with the extension of the time of implementing the epitaxial growth process 108, in addition to continue to face towards the direction perpendicular to the inclined surface of each island 100a, the un-doped semiconductor epitaxial layer 110b (see FIG. 25) higher than the dielectric barrier layer 106 and the islands 100a also faces towards the un-doped semiconductor epitaxial layer 110b horizontal to the adjacent island 100a to side merge into the un-doped semiconductor epitaxial layer 110 having the flat surface.

As shown in FIG. 26, the recess structure 100b between adjacent islands 100a is not filled with this un-doped semiconductor epitaxial layer 110 at this time, while no gap may exist among each recess structure 100b between the un-doped semiconductor epitaxial layer 110 and the adjacent island 100a and the adjacent dielectric barrier layer 106 as well as the un-doped semiconductor epitaxial layer 110.

As shown in FIG. 26, the formed un-doped semiconductor epitaxial layer 110 performs the epitaxial growth from the inclined surface of the sidewall 100c of each island 100a in the patterned substrate as shown in FIG. 24, therefore, the epitaxial direction in the formed un-doped semiconductor epitaxial layer 110 may be controlled, thereby reducing the defect density between the material of the un-doped semiconductor epitaxial layer 110 and the material of the substrate 100. Therefore, since the un-doped semiconductor epitaxial layer 110 formed on the patterned substrate shown in FIG. 26 has less defect problems, it may have the better epitaxial quality, so it is beneficial to improve photoelectric efficiency and reliability of the electronic element and the photoelectric element such as the LED formed thereon.

Referring to FIG. 27, then, the conventional process (not shown) may be employed to form the light emitting element 170 in the above embodiment on the un-doped semiconductor epitaxial layer 110. Since the un-doped semiconductor epitaxial layer 110 exists below the light emitting element 170, the defect problems are less and the epitaxial quality is better, such that the efficiency and reliability of the light emitting element 170 formed on the un-doped semiconductor epitaxial layer 110 may be improved. Additionally, since several dielectric barrier layers 106 are formed below the un-doped semiconductor epitaxial layer 110, and since different refraction coefficients exist among the dielectric barrier layer 106 and the substrate 100 and the un-doped semiconductor epitaxial layer 110, the light emitted from the active layer 152 may be refracted and reflected by these dielectric barrier layers 106 to enhance the light extraction efficiency of the light emitting element 170.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A patterned substrate, comprising:
a substrate having a (0001) crystal plane and a plurality of alternatively arranged recess structures therein, thereby forming a plurality of alternatively arranged top surfaces on the substrate, wherein each of the recess structures comprises a bottom surface and a plurality of sidewalls surrounding the bottom surface; and
a dielectric barrier layer covering either the bottom surface or the sidewalls of the recess structures or the bottom surface and the sidewalls of the recess structures.

2. The patterned substrate as claimed in claim 1, wherein the dielectric barrier layer further covers all or a part of each of the top surfaces of the substrate.

3. The patterned substrate as claimed in claim 2, wherein each of the top surfaces is substantially a flat surface or a curved surface.

4. The patterned substrate as claimed in claim 1, wherein the bottom surface is the (0001) crystal plane.

5. The patterned substrate as claimed in claim 1, wherein the dielectric barrier layer is made of silicon dioxide, silicon nitride, or titanium dioxide.

6. The patterned substrate as claimed in claim 1, wherein the substrate is made of sapphire, silicon, or silicon carbon.

7. A stacked light emitting diode, comprising:
the patterned substrate as claimed in claim 1;
an undoped semiconductor epitaxial layer disposed over the dielectric barrier layer and the substrate; and
a light emitting element disposed on the undoped semiconductor epitaxial layer.

8. The stacked light emitting diode structure as claimed in claim 7, wherein the undoped semiconductor epitaxial layer is disposed over the top surfaces of the substrate, forming a plurality of gaps between the recess structures and thereof.

9. The stacked light emitting diode structure as claimed in claim 7, wherein the undoped semiconductor epitaxial layer is disposed over the substrate and fills the recess structures.

10. The stacked light emitting diode structure as claimed in claim 9, wherein the light emitting element comprises:
an n-type semiconductor epitaxial layer disposed on the undoped semiconductor epitaxial layer;
an active layer disposed on a portion of the n-type semiconductor epitaxial layer, exposing a portion of the n-type semiconductor epitaxial layer;
a p-type semiconductor epitaxial layer disposed over the active layer;
a first electrode disposed on the exposed portion of the n-type semiconductor epitaxial layer; and
a second electrode disposed on the p-type semiconductor epitaxial layer.

11. The stacked light emitting diode structure as claimed in claim 10, wherein the n-type semiconductor epitaxial layer is a Si-doped n-type semiconductor epitaxial layer, and the p-type semiconductor epitaxial layer is a Mg-doped p-type semiconductor epitaxial layer.

12. The stacked light emitting diode structure as claimed in claim 10, wherein the light emitting element further comprises a transparent conductive layer disposed between the second electrode and the p-type semiconductor epitaxial layer.

13. The stacked light emitting element as claimed in claim 8, wherein each one of the gaps has a height ranging from 0.1-2 μm.
